(19) United States
(12) Patent Application Publication
(10) Pub. No.: US 2015/0248994 A1
(43) Pub. Date: Sep. 3, 2015

(54) PLASMA PROCESSING APPARATUS

(71) Applicant: Hitachi High-Technologies Corporation, Tokyo (JP)

(72) Inventors: Takumi TANDOU, Tokyo (JP); Kohei SATO, Tokyo (JP); Hiromichi KAWASAKI, Tokyo (JP); Akitaka MAKINO, Tokyo (JP)

(21) Appl. No.: 14/463,685

(22) Filed: Aug. 20, 2014

(30) Foreign Application Priority Data
Feb. 28, 2014 (JP) 2014-037691

(51) Int. Cl. H01J 37/32; H01L 21/683; H01L 21/67

(52) U.S. Cl. CPC H01J 37/32724; H01J 37/32458; H01L 21/67069; H01L 21/6831; H01J 2237/334

(57) ABSTRACT

A plasma processing apparatus, comprising a processing chamber within a vacuum chamber, and a sample stage arranged within the processing chamber with a sample to be processed placed on its top surface, wherein plasma is formed in the processing chamber to perform processing of the sample, wherein the sample stage is provided with an electrostatic chuck which is provided with film electrodes to which power for attraction of the sample is supplied, and upper and lower plate-like sintered bodies joined mutually with the electrodes interposed between them from above and below, and the lower sintered body has a dielectric constant higher than that of the upper sintered body.

### BACKGROUND OF THE INVENTION

The present invention relates to a plasma processing apparatus that processes a film structure to be processed, which is placed on the top surface of a substrate-like sample such as a semiconductor wafer arranged in a processing chamber within a vacuum container, by using plasma formed within the processing chamber, and particularly relates to processing performed by placing the sample on a mounting surface formed of a dielectric body on the top surface of a sample stage arranged within the processing chamber and holding it by attracting with static electricity.

With the trend of miniaturization of a semiconductor device, processing precision required by the sample etching process is becoming higher. In order to realize the requirement, it is important to perform with higher precision so-called temperature control for adjusting the temperature of the wafer surface to a value in a range suitable for processing during plasma processing, for example, etching processing.

In addition, when processing of a film to be processed is performed by a process consisting of a plurality of steps, it is required in these years to change the temperature in an etching step without taking the sample wafer out of the processing chamber. In order to realize the requirement, there are demands for a technology to adjust the sample temperature quickly and accurately. To adjust the temperature of the front surface of the sample facing toward the plasma, the above plasma processing apparatus adjusts conventionally the temperature of the top surface of the sample stage in contact with the back surface of the sample to a predetermined value range.

The sample stage according to the conventional technology has a structure provided with, for example, an electrostatic chuck which forms a mounting surface, on which the sample stage is placed, on an upper part of a metal cylindrical or circular member. The electrostatic chuck holds a wafer by attracting it on the top surface of a member, which has a film shape formed of the dielectric material or a disk shape having a small thickness enough capable of forming an electrostatic force, by the electrostatic force formed by using the DC power supplied to the electrodes arranged within the member and supplying He gas as a medium for heat transfer to between the wafer and the film top surface in the above state to promote the heat transfer between them. With the above structure, the magnitude of the electrostatic attraction force by the electrostatic chuck has a dominant influence on the heat transmitting characteristics between the sample stage and the wafer.

That is, the temperature of the wafer, which is a sample to be processed, is varied by a change in the electrostatic attraction force by the electrostatic chuck. On the other hand, when the top surface of a member formed of the dielectric body forming the top surface of the electrostatic chuck does not have a wafer on it, it is exposed to a gas or fine particles supplied to the space within the processing chamber or its inside, and further to plasma formed in order to clean the surface inside the processing chamber with the wafer not positioned. Therefore, the top surface of the electrostatic chuck is deformed with an increase of the processed number of wafers or the processing (operation) time, and a contact area between the wafer and the top surface of the electrostatic chuck and accordingly the electrostatic attraction force are changed as a result. In order to reduce the problem, a Coulomb system using ceramics of high purity as a dielectric material which forms the surface as a system of forming the electrostatic force is proposed as an attraction system which has little change in attraction force even if minute shapes on the electrode surface are changed when exposed to the plasma.

For example, in a case where alumina (Al₂O₃) is used as ceramics for a dielectric material for the electrostatic chuck and exposed to plasma using a fluorine-based gas, a member formed of the alumina is scraped by interaction with the plasma, and contaminating matters are generated in a processing chamber. As means for solving the problem by reducing the generated amount of the contaminating matters, it is considered to use a sintered body of ceramics as the dielectric material for the above-described electrostatic chuck upper part. That is, as a method of forming a ceramics film for realization of the electrostatic chuck, it is known to adopt thermal spraying or the like, but when a sintered body having ceramics crystals more closely combined mutually is used, an amount of consumption by the plasma is reduced, and the generated amount of the contaminating matters can be suppressed.

As examples of the above conventional technologies, it is known as disclosed in, for example, JP-A-9-148420 that an electrostatic chuck sintered body, which is an electrostatic attraction member, is arranged in a state divided into a plurality of parts on an electrode block, a film of an insulating material is formed on the electrode block, to which the electrostatic attraction member is fixed, by thermal spraying, and the electrostatic chuck sintered body is exposed by polishing the insulating material. According to the above conventional technology, electrostatic attraction characteristics can be determined according to a physical property value of the sintered body, and an electrostatic chuck surface can be formed by a combination of the sintered bodies of small members.

It is disclosed in JP-A-2004-349666 that a sintered body of aluminum nitride is used as an electrostatic chuck film. According to this conventional technology, aluminum nitride on the surface and a plurality of sintered bodies are undergone compression bonding at the same time under a high temperature condition, and an attraction force is uniformized by determining the volume resistivity of a sintered plate that an attraction surface side is smaller than other portion. Thus, even when the wafer is made to have a large diameter, a sure attraction force is secured, and an electrostatic chuck capable of operating at a high temperature can be provided at a low price.

### SUMMARY OF THE INVENTION

The above conventional technology had a problem because consideration on the following points was not sufficient. That is, JP-A-9-148420 has a structure that the sintered body and the thermal sprayed film are coexisted on the sample mounting surface, and it is hard to suppress contaminating matters from generating. Therefore, no consideration was made by the above conventional technology on the point that the sample processing yield was impaired.

When the structure according to JP-A-2004-349666 is adopted, attraction by the Coulomb system cannot be made because the sintered body of aluminum nitride is used for the most surface contacted to the sample. For the volume resistivity of the sintered body, it is determined that the volume resistivity value of an attraction surface side portion is smaller than the volume resistivity value of other portion. Therefore, the above conventional technology did not give consideration on a structure for generating an electrostatic attraction force capable of holding a large-diameter wafer while the strength of the sintered body is maintained if the diameter of the wafer as the sample is increased in the future. Therefore, the wafer processing temperature cannot be adjusted to a desired range, and there was a possibility that the yield of the processing is impaired.

The present invention provides a plasma processing apparatus which has a processing yield improved.

The above object can be achieved by a plasma processing apparatus, comprising a processing chamber arranged within a vacuum chamber with its inner space decompressed, and a sample stage arranged within the processing chamber with a sample to be processed placed on its top surface, wherein plasma is formed using a process gas supplied into the processing chamber above the sample stage to perform processing of the sample, wherein the sample stage is provided with a metal block which has therein a passage for flowing a coolant and to which high frequency power is supplied during the processing of the sample and an electrostatic chuck which is arranged on the block and on which the sample is positioned and electrostatically chucked, and the electrostatic chuck is provided with film electrodes to which power for attraction of the sample is supplied, and upper and lower plate-like sintered bodies joined mutually with the electrodes interposed between them from above and below, and the lower sintered body has a dielectric constant higher than that of the upper sintered body.

### BRIEF DESCRIPTION OF DRAWINGS

FIG. 1 is a longitudinal sectional view schematically illustrating an outline of the structure of a plasma processing apparatus according to an embodiment of the present invention.

FIG. 2 is a longitudinal sectional view schematically showing an outline of the structure of a sample stage according to the embodiment shown in FIG. 1,

FIGS. 3A and 3B are longitudinal sectional views each schematically showing an outline of the structure of a sintered body on the sample stage shown in FIG. 2.

FIGS. 4A and 4B are graphs each schematically showing an impedance characteristic of a sintered body according to the embodiment shown in FIG. 1.

FIG. 5 is a longitudinal sectional view schematically showing an outline of the structure of a sample stage according to a modification of the embodiment shown in FIG. 2.

### DESCRIPTION OF EMBODIMENTS

Embodiments of the invention are described below with reference to the drawings.

In a case where an electrostatic chuck that is formed of a ceramics sintered body is installed on an electrode block, for example, it is manufactured through the following processes.

(1) Internal electrodes for electrostatic attraction are patterned on a ceramics green sheet by printing or the like, the internal electrodes are coated with another green sheet, and sintering is performed under a high temperature and a high pressure.

(2) The ceramics is polished to obtain a prescribed thickness and flatness. After the surface polishing, the surface shape is processed if necessary.

(3) The above-manufactured electrostatic chuck is positioned and fixed onto the electrode block with an adhesive. Finishing is performed if necessary. A coolant passage is formed within the electrode block.

The sample stage on which the sintered body is formed into an electrostatic chuck film is completed through the above processes. At this time, the thicker the ceramics is, the lower a risk of cracks from occurring becomes at the time of processing or handling. That is, it is necessary to design the ceramics sintered body thick to manufacture the sample stage stably. But, when the ceramics layer is formed thick, the sintered body member has an increased impedance, and when a high frequency power is applied to the electrode block, the sintered body becomes a component of the impedance, and a high frequency electric current is hindered.

Thus, it becomes hard to apply a high frequency voltage to a sheath formed on a wafer during plasma etching, and an adverse effect of degrading etching characteristics is generated. As the wafer diameter increases from 300 mm to 450 mm in future, it is expected that a manufacturing difficulty level of the sintered body for the above-described electrostatic chuck increases furthermore, and it is expected that a trade-off issue between the manufacturing yield and the etching characteristics is becoming obvious increasingly. The following is considered as an example of the above trade-off accompanying an increase in the wafer diameter.

Ceramics produced by sintering powder has a large number of defects (cracks). Since the ceramics has generation of breaks at the weakest point in its face, its strength tends to decrease as the ceramics has a larger area, and the probability of breakage increases.

When the wafer diameter is increased from 300 mm to 450 mm, the area is increased by 2.25 times, and the probability of breakage simply becomes 2.25 times or more. Since it also becomes hard to sinter the whole ceramics homogeneously and densely because its area has become large, the probability of breakage increases furthermore.

To prevent the ceramics from breaking, it is necessary to suppress a stress that is generated in the ceramics by an external force, and the thickness of the ceramics must be increased. Here, for example, when the top surface of the electrode block is worked by a lathe, a center part of a flat surface has a recess shape. Therefore, when a ceramics plate having an electrostatic chuck function is then placed to perform processing for applying and finishing process, it becomes a stress model of “a disk which receives a uniformly distributed load supported on a circumference”.

In such a case, the maximum stress generated in the ceramics is proportional to the square of the radius of the ceramics and inversely proportional to the square of the thickness of the ceramics. When the ceramics diameter is increased from 300 mm to 450 mm and it is assumed that a breakage probability is increased by 4.5 times, namely an allowable stress becomes 1/4.5 as described above, it is necessary to increase the thickness of the ceramics by 3.2 times. When the ceramics area is increased by 2.25 times and the thickness is increased by 3.2 times, the electrostatic capacitance of the ceramics is increased by about 0.7 time, and the impedance is increased by about 1.4 times. When the ceramics thickness is reduced in order to suppress the impedance, the processing yield in manufacturing lowers, and there is a possibility that stable manufacturing of industrial products becomes difficult.

In an embodiment of the present invention, the plasma processing apparatus has a sample stage mounted in a vacuum container, produces plasma from a process gas introduced into the vacuum container, and performs surface processing of a sample to be processed placed on the sample stage by the plasma. The sample stage is configured by adhering an electrostatic attraction layer onto an electrode block having a passage for a heat exchange medium, the electrostatic attraction layer is formed by joining two layers of sintered bodies, the internal electrodes are positioned on the joining surface of the sintered bodies, and the dielectric constant of the sintered body where the sample is placed is lower than that of the other sintered body.

The electrostatic attraction layer is formed by joining two layers of sintered bodies, the internal electrodes are positioned on the joining surface of the sintered bodies, the dielectric constant of the sintered body where the sample is placed is lower than that of the other sintered body, and the thickness of the sintered body where the sample is placed is smaller than that of the other sintered body.

According to the above embodiment, the dielectric constant of the lower sintered body material for the electrostatic attraction layer, which is provided with the upper sintered body and the lower sintered body arranged below it, is made higher than that of the upper sintered body, so that the lower sintered body keeps its impedance low even when its thickness is increased. That is, the electrostatic attraction layer which is configured by joining the upper and lower sintered bodies is determined to have a thickness in a range suitable for processing and manufacturing so that the total impedance of the sintered bodies falls in a range suitable for processing in vertical direction. That is, both efficient application of an RF voltage to the wafer sheath and realization of a high processing yield are established.

As an example of means for increasing the dielectric constant of the lower sintered body material, it is considered to add metal powder or the like. When the upper sintered body which is contacted to the back surface of the wafer is formed of ceramics not containing metal powder or the like or a mixture of a plurality of ceramics, it becomes possible to realize an electrostatic chuck by the Coulomb system with the upper sintered body formed of an electrostatic chuck film, and a change with time of the wafer temperature or generation of contaminating matters are suppressed when the surface of the sample stage is exposed to the plasma.

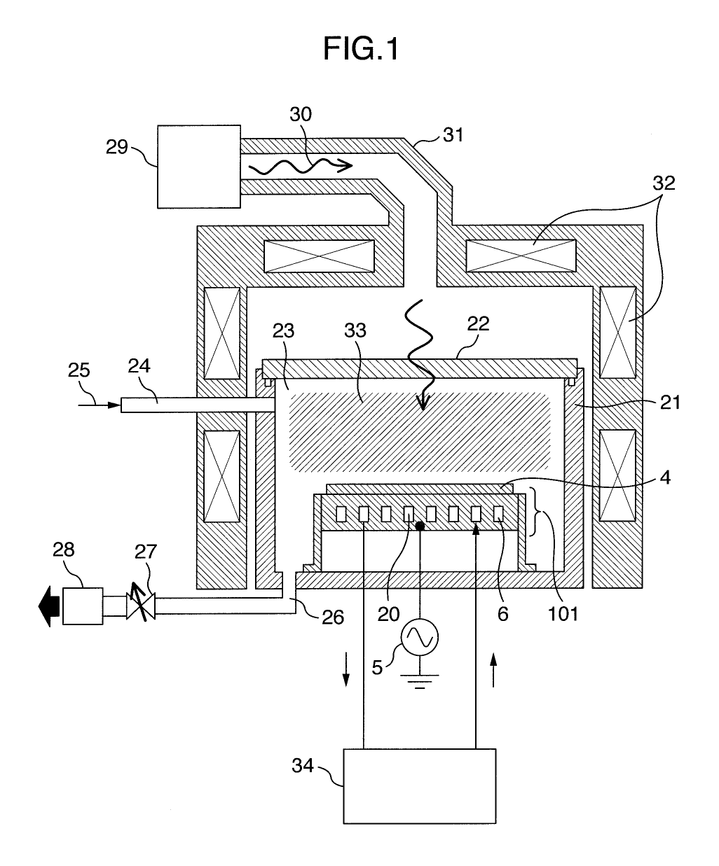

An embodiment of the invention is described with reference to FIGS. 1 to 4.

FIG. 1 is a longitudinal sectional view schematically illustrating an outline of the structure of a plasma processing apparatus according to an embodiment of the invention. Specially, it is a view showing a structure of a microwave ECR plasma etching system using ECR (Electron Cyclotron Resonance) by an electric field and a magnetic field of a microwave 30 to form plasma within a processing chamber by exciting gas particles within the processing chamber.

The plasma processing apparatus of this embodiment is provided with a plasma forming part including a cylindrical vacuum container having therein a processing chamber 23 in which plasma 33 is formed and means which is arranged above and around the side of the cylindrical vacuum container and generates an electric field or a magnetic field to form the plasma 33 in the processing chamber 23, and a pumping apparatus which is means arranged below the vacuum container, exhausts the plasma 33 and the gas within the processing chamber 23, particles such as byproducts formed within the processing chamber 23 and provided with a vacuum pump such as a turbo-molecular pump 28. The processing chamber 23 has therein a sample stage 101 arranged at a lower position with a sample 4 placed on its top surface and held by attracting by means of static electricity.

The processing chamber 23 is a cylindrical space which is arranged within the vacuum container to form the plasma 33 therein and surrounded by a processing chamber wall 21 which is a cylindrical member. At an upper part in the processing chamber 23, a processing chamber lid 22, which is formed of a dielectric body (quartz glass in this embodiment), is placed on the upper end of the processing chamber wall 21 with a seal member held therebetween to configure a top portion of the vacuum container. Thus, the inside of the processing chamber 23 and the atmosphere of an outside location where the plasma processing apparatus is installed are separated airtightly from each other.

A gas introduction pipe 24 is arranged above the processing chamber wall 21, and a process gas 25 for performing an etching process is supplied from an upper part in the processing chamber 23 and above the sample stage 101 into the processing chamber 23 via an opening of the gas introduction pipe 24. The gas introduction pipe 24 is coupled with an unshown tank, which is a gas source, via a gas supply pipe, and the gas supply pipe is provided with a flow regulator for adjusting the flow rate or the speed of the process gas 25 and a vale for opening and closing the pipe line. An exhaust port 26, which is connected to the turbo-molecular pump 28, is arranged at a lower part in the processing chamber 23 and on the bottom surface of the vacuum container below the sample stage 101, and the process gas 25 introduced into the processing chamber 23 and byproducts produced by etching are exhausted through the exhaust port 26 by the operation of the pump 28.

An exhaust path, which connects the exhaust port 26 and the turbo-molecular pump 28 which is a type of vacuum pump, has thereon a pressure regulating valve 27 which has a plate (flap) shape arranged to increase or decrease a cross-sectional area of the exhaust passage by rotating about the axis crossing a flow direction of the exhaust gas flowing inside the path. An opening degree of the passage is increased or decreased by the pressure regulating valve 27 to adjust a flow rate or a speed of the exhaust gas from the processing chamber 23. And the pressure in the processing chamber 23 is adjusted to a value (2 to 5 Pa) in a range suitable for processing by balance of the exhaust gas and a flow rate or a speed of the process gas 25 supplied to the processing chamber 23.

An electric field forming apparatus, which configures a plasma forming part, is arranged above the vacuum container which is at an upper part of the processing chamber 23. In this embodiment, there is provided a waveguide 31 through which (an electric field of) the microwave 30 propagates toward the processing chamber 23 or the processing chamber lid 22 arranged above it. The waveguide 31 has a cylindrical part which has a cylindrical cross section and extends vertically with its one end (lower end in the drawing) arranged opposite to the top surface of the processing chamber lid 22, and a rectangular part which has a rectangular cross section and extends in a horizontal direction (right and left directions in the drawing) with its one end connected to the other end (upper end in the drawing) of the cylindrical part. And a microwave oscillator 29 such as a magnetron which forms (an electric field of) the microwave 30 by oscillating is arranged at the other end (a left end in the drawing) of the rectangular part. The microwave 30 generated by the microwave oscillator 29 propagates downward through the rectangular part and the cylindrical part, and it is introduced into a cylindrical cavity part, which is arranged above the processing chamber lid 22 and has a diameter equal to that of the processing chamber 23 and larger than that of the cylindrical part, and oscillated in the cavity part to form an electric field of a prescribed mode which is then introduced into the processing chamber 23 from above through the processing chamber lid 22 which is at the top of the processing chamber 23.

Furthermore, solenoid coils 32, which form a magnetic field generator, are arranged above the processing chamber lid 22 and the outer circumference of the processing chamber wall 21 to surround the processing chamber 23. The generated magnetic field is introduced into the processing chamber 23 and, by an interaction with the electric field of the microwave 30 introduced passing through the processing chamber lid 22, atoms or molecules of the process gas 25 supplied into the processing chamber 23 are excited, and the plasma 33 is formed in a space (discharge space) above the sample stage 101. A plasma etching process is performed by interacting the charged particles such as ions formed by the plasma 33 and highly reactive particles (active species) with a film to be processed having a film structure arranged on the top surface of the sample 4.

In this embodiment, to adjust the temperature of the sample 4 as a semiconductor wafer or the sample stage 101 to a value in a range suitable for processing, a coolant with its temperature adjusted by a temperature adjusting unit 34 is supplied to a coolant passage 6 arranged within a substrate which is a cylindrical or disk member made of metal configuring the sample stage 101. The coolant such as water or Fluorinert (Trade Mark) with its temperature adjusted to a value in a prescribed range by the temperature adjusting unit 34 such as a chiller unit, flows through a coolant supply pipe into the inlet of the coolant passage 6 which has a spiral shape or a concentrical shape arranged in a multiple manner around the center axis within the substrate of the sample stage 101, performs heat exchange with the substrate and accordingly with the sample 4 to increase the temperature while flowing through the coolant passage 6, and flows out of the outlet of the coolant passage 6. The flown-out coolant returns to the temperature adjusting unit 34 through the coolant exhaust pipe, cooled again to a temperature having a value in the prescribed range, and supplied again to the sample stage 101 through the coolant supply pipe to circulate.

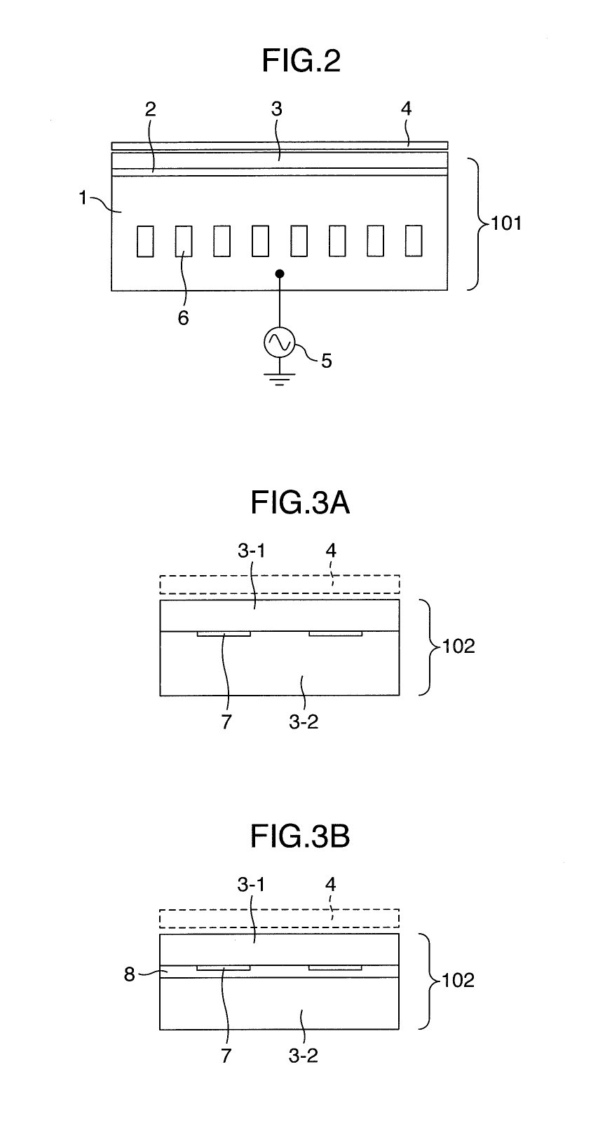

FIG. 2 is a longitudinal sectional view schematically showing an outline of the structure of the sample stage according to the embodiment shown in FIG. 1. FIG. 2 does not show coolant supply and exhaust pipes for connecting the temperature adjusting unit 34 for adjusting the temperature of the coolant and the sample stage 101 shown in FIG. 1, a film electrode which forms an electrostatic force with the sample 4 with a member made of a dielectric body therebetween when DC power is supplied and a power source for supplying the DC power.

In this embodiment, the sample stage 101 is provided with an electrode block 1 which has a cylindrical or disk shape, configures a substrate made of a conductor (metal in this embodiment) and has therein the coolant passage 6 in which a heat exchange medium passes to circulate, and a sintered body 3 which has a disk shape and an electrostatic attraction function and is arranged above the circular top surface of the electrode block 1 with a first adhesive layer 2 having electrical insulating characteristics held therebetween. The top surface of the sintered body 3 configuring the electrostatic chuck forms a mounting surface for the sample 4, and the sample 4 is mounted on it and held by an electrostatic attraction force.

The electrode block 1 is a conductor member, electrically connected to a high frequency power source 5 and applied with a high frequency power. While the sample 4 is electrostatically chucked to the top surface of the sintered body 3 and processed, the electrode block 1 is supplied with a high frequency (4 MHz in this embodiment) power from the high frequency power source, and a bias potential is formed according to the potential of the plasma 33 above the top surface of the sample 4 held on the electrostatic chuck. The charged particles such as ions in the plasma 33 are attracted to the top surface of the sample 4 by the potential difference between the bias potential and the plasma 33 and collided with the film to be processed to promote the film etching process.

To keep (to cool in this embodiment) the temperature of the sample 4 heated by the collision of the charged particles in a temperature range suitable for the processing, the coolant is supplied to the coolant passage 6 within the electrode block 1 to cool the electrode block 1 and accordingly the sample 4. Since the temperature of the sample 4 is determined according to the balance between an amount of heat input from the plasma 33 to the electrode block 1 via the sample 4 and the electrostatic chuck and an exhaust heat amount transmitted from the electrode block 1 to the coolant, the temperature of the sample 4 can be realized to have a value in a desired range by adjusting the temperature or the circulating amount of the supplied coolant.

And, with the sample 4 electrostatically chucked to the sintered body 3 of the electrostatic chuck configuring the upper part of the sample stage 101 in this embodiment, He gas is supplied as a heat transfer medium to between the front surface of the sintered body 3 and the back surface of the sample 4. Thus, the heat transmission between the sample stage 101 and the sample 4 is promoted, and precision and efficiency of adjusting the temperature of the sample 4 are improved. As described above, since the electrostatic attraction force to the electrostatic chuck of the sample stage 101 and particularly to the sample 4 on the top surface of the sintered body 3 influences on properties and efficiency of heat transmission, if the electrostatic attraction force varies, the temperature of the sample 4 changes similarly.

FIGS. 3A and 3B are longitudinal sectional views each schematically showing an outline of the structure of the sintered body on the sample stage shown in FIG. 2. FIG. 3A shows an example of an electrostatic chuck 102 which has therein internal electrodes 7 arranged within the sintered body 3 and supplied with DC power for electrostatic attraction, a first sintered body 3-1 arranged on the internal electrodes 7, a second sintered body 3-2 arranged under the same, and the internal electrodes 7 arranged between the first sintered body 3-1 and the second sintered body 3-2.

As described above, since the change of the electrostatic attraction force affects the temperature change of the sample 4, even if a sample mounting surface which is the top surface of the first sintered body 3-1 is exposed to the charged particles, active species having high reactivity, etc. included in the plasma 33 and deformed in shape by interaction, it is required that a change in electrostatic attraction force can be suppressed. To achieve it, a Coulomb system is used in this embodiment. The Coulomb system in this embodiment uses a material having a high resistivity as a dielectric material configuring the first sintered body 3-1, for example, ceramics with impurities in a very small content, for example, pure alumina or a plurality of ceramics mixtures containing pure alumina.

In a case where alumina is used as the first sintered body 3-1, if its surface portion is scraped by interaction due to exposure to fluorine-based reaction active species, there is a possibility of contaminating the sample 4 to be processed due to generation of contaminating matters in the processing chamber. Therefore, this embodiment has the internal electrodes 7 within the electrostatic chuck 102 and forms the sintered body 3 by calcining a dielectric body coated on it.

Conventionally, a technology of thermal spraying or the like has been used to form a member made of a dielectric body for the electrostatic chuck. On the other hand, this embodiment can improve the yield of the processing by using the sintered body 3 which is a member having ceramics crystals more closely combined mutually to reduce the consumption of the dielectric material exposed to the reaction active species or the charged particles and to suppress the contaminating matters from generating.

If it is hard to form the first sintered body 3-1 and the second sintered body 3-2 by integrally calcining in FIG. 3A, the structure shown in FIG. 3B may be adopted. That is, FIG. 3B shows an example showing a structure that the internal electrodes 7 for electrostatic attraction are held between the first sintered body 3-1 and the second sintered body 3-2, and the electrostatic chuck 102 is formed by adhering the first sintered body 3-1 and the second sintered body 3-2, which are formed by separately calcining in advance with a second adhesive layer 8 interposed between them.

In this embodiment, the adhesive layer 8 is coated and arranged on the entire top surface of the second sintered body 3-2, and the internal electrodes 7 are arranged on the bottom surface of the first sintered body 3-1 by a known conventional technology of thermal spraying or coating. Subsequently, the first sintered body 3-1 and the second sintered body 3-2 are integrally formed by joining with the internal electrodes 7 and the adhesive layer 8 interposed between them.

Here, this embodiment is desirable that the electrostatic chuck 102 is formed thick to improve the yield in manufacturing the electrostatic chuck 102 formed of the sintered body. That is, the thicker the total thickness of the first sintered body 3-1 and the second sintered body 3-2, the lower a risk of cracks occurring at the time of processing or handling can be made, and the yield can be improved.

On the other hand, however, when the sintered body is formed thick, the impedance of the electrostatic chuck 102 increases, the electrostatic chuck 102 becomes a component of the impedance when a high frequency power is applied to the electrode block 1, and a high frequency electric current is hindered. Thus, there is a possibility that it is hard to form a bias potential capable of colliding the charged particles in the plasma 33 sufficiently to perform processing with desired precision and speed above the top surface of the sample 4. Therefore, it is necessary to determine a range of dimensions for establishing both the manufacturing yield by the electrostatic chuck 102 and the performance of processing the sample 4.

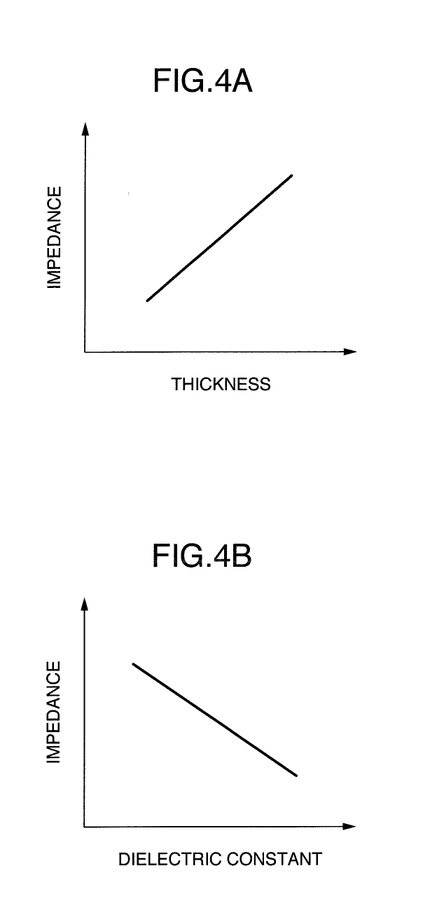

FIGS. 4A and 4B are graphs each schematically showing an impedance characteristic of the sintered body according to the embodiment shown in FIG. 1. As described above, the impedance increases with an increase in thickness at the sintered body part of the electrostatic chuck 102 as shown in FIG. 4A. On the other hand, the impedance decreases with the increase of the dielectric constant of the sintered body as shown in FIG. 4B.

Thus, the inventors have obtained the knowledge that there is a range of thickness dimension capable of suppressing the impedance to a low level such that the desired processing performance can be obtained by increasing the dielectric constant of the second sintered body 3-2 to obtain a material strength sufficient to obtain a desired yield by the second sintered body 3-2. The invention according to this embodiment has been obtained on the basis of the above knowledge.

In this embodiment, the second sintered body 3-2 is determined to have its dielectric constant higher than that of the first sintered body 3-1. As an example of means for increasing the dielectric constant, a metal powder or the like is added to the dielectric material, dispersed uniformly and calcined in this embodiment.

In this embodiment, since the member forming the second sintered body 3-2 has metal additive particles uniformly arranged in both directions and thickness direction around the whole of the dielectric material, the second sintered body 3-2 has a volume resistivity which is relatively lower than that of the one with the same material and dimensions without addition of the additive particles. Accordingly, an increase in impedance of the second sintered body 3-2 against the high frequency power is suppressed, a difference between the bias potential above the sample 4 and the potential of the plasma 33 is suppressed from lowering, and a desired processing rate can be realized.

Since the above-described attraction according to the Coulomb system is desirable, the first sintered body 3-1, which is in contact with the back surface of the sample 4, is formed of ceramics such as alumina not containing impurities such as metal powder or a mixture of a plurality of types of ceramics. Therefore, in the embodiment described above, the dielectric constant of the second sintered body 3-2 becomes higher than that of the first sintered body 3-1.

This embodiment has a possibility that a current of the DC power from the internal electrodes 7 via the second sintered body 3-2 leaks due to the presence of the additives. In this embodiment, the first adhesive layer 2 which is formed of an insulating material is arranged between the second sintered body 3-2 and the electrode block 1, so that they are insulated from each other and a leak current is prevented from flowing.

The thickness of the second sintered body 3-2 using as a material the dielectric body having the dielectric constant described above is determined to increase the strength of the electrostatic chuck 102 integrally joined with the first sintered body 3-1 so that the manufacturing yield can be suppressed from decreasing. On the other hand, the first sintered body 3-1, which is arranged above with the internal electrodes 7 interposed, is required to form static electricity capable of generating an attraction force suitable for processing the sample 4. To realize the requirement, it is desired that the dielectric constant is smaller or the thickness is smaller.

That is, the first sintered body 3-1 is desirably designed thin in view of securing the electrostatic attraction force (increasing a Coulomb force), so that the total thickness of the electrostatic chuck 102 that can satisfy both the manufacturing yield and the exhibition of attracting or processing performance can be realized by appropriate selection of the thickness values of the first sintered body 3-1 and the second sintered body 3-2 or their ratio. In this embodiment, the thickness of the second sintered body 3-2 is determined to be larger than that of the first sintered body 3-1.

With the above configuration, the first sintered body 3-1 suppresses a change with time of the attraction force and the generation of the contaminating matters, and the second sintered body 3-2 achieves both the manufacturing yield and the processing performance. And, if the wafer diameter increases to a large diameter, it is expected that a manufacturing difficulty level of the electrostatic chuck 102 increases furthermore, and means of establishing both the manufacturing yield and the processing performance according to the present invention is considered useful.

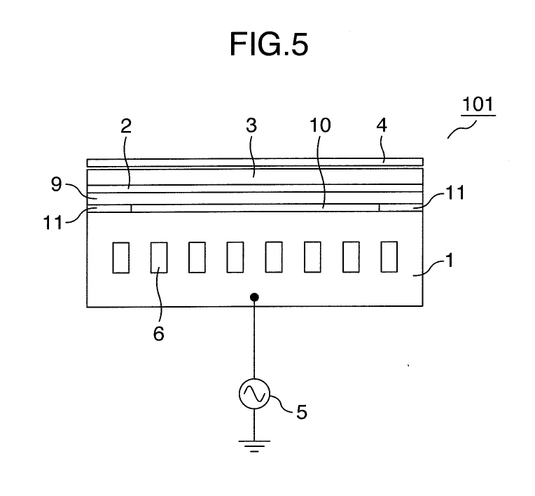

A modification of this embodiment is described below with reference to FIG. 5, FIG. 5 is a longitudinal sectional view schematically showing an outline of the structure of a sample stage according to a modification of the embodiment shown in FIG. 2. In the following description, the same configuration of FIG. 5 as that of the embodiment shown in FIG. 2 is omitted from the description.

Differences between the structure of the sample stage 101 according to this modification of the embodiment shown in FIG. 5 and the embodiment shown in FIG. 2 include provision of a metal conductor 9 which is arranged below the electrostatic chuck 102 and above the electrode block 1 so to be interposed between them, an insulator 10 which is arranged below it, and a conductive connection layer 11 which is arranged along the outer periphery of the insulator 10 to join the electrode block 1 and the conductor 9. When the temperature of the sample 4 is adjusted in a range larger than in the embodiment or adjusted quickly or accurately, a heater element, which generates heat upon receiving power while being adjusted from an unshown DC power source, may be arranged within the insulator 10.

To operate the heater element more effectively, it may be arranged at a position higher than the center in the thickness direction within the insulator 10, namely a relatively higher position close to the conductor 9. With this configuration, the heater element is determined to have a relatively close distance to the sample 4, and temperature adjusting efficiency of the sample 4 by heating by the heater is improved. As a material for the heater element in this embodiment, metal such as stainless steel or tungsten is used.

The metal conductor 9, which has a disk shape, a diameter same as that of the sintered body 3 or an approximate diameter regarded as the same, high conductivity and heat conductance, is arranged above the insulator 10 having a disk shape and below the sintered body 3 or the adhesive layer 2 and in contact with the top surface of the insulator 10. When the conductor 9 is arranged and the high frequency power supplied to the electrode block 1 is transmitted upward passing through the insulator 10, even if the magnitude of the passing high frequency power has distribution of an increase and a decrease occurring in an in-plane direction of the top surface of the insulator 10 because the metal heater element exists on the transmission path within it, the distribution is reduced because the high frequency power flows into the conductor 9, and the magnitude of the high frequency power comes to have a state closer to homogeneity on the top surface of the conductor 9.

That is, the conductor 9 has a function to nearly uniformize the distribution of the high frequency power or a bias potential by it in both directions of the electrostatic chuck 102 or the sample 4. And, the conductor 9 may be made to function as a thermal diffusion plate (soaking plate) regardless of the presence or not of the heater element. And temperature in surfaces of the electrostatic chuck 102 or the sample 4 can be made more uniform by selecting a material having a high coefficient of thermal conductivity.

And, the sintered body 3 having an electrostatic attraction function is arranged above and joined with the conductor 9 with the first adhesive layer 2 having electrical insulating characteristics interposed between them to form the electrostatic chuck 102. As described above, the top surface of the sintered body 3 is a mounting surface for the sample 4, and the sample 4 is mounted on it and held by being attracted onto the top surface of the first sintered body 3-1 forming the upper part of the sintered body 3 by static electricity formed by the DC power supplied to the internal electrodes 7 arranged within the sintered body 3.

Similar to the above embodiment, the electrode block 1 is electrically connected with the high frequency power source 5, and the high frequency power is supplied from the high frequency power source 5 during processing. Thus, the etching process is promoted by forming a bias potential above the first sintered body 3-1 at the upper part of the sample stage 101 or the sample 4 to attract the charged particles in the plasma 33 to the sample 4.

Similar to the embodiment of FIG. 2, to cool the sample 4 heated by collision of the charged particles such as ions in the plasma 33, the coolant is supplied to the coolant passage 6 in the electrode block 1, and the electrode block 1, and accordingly the electrostatic chuck 102 or the sample 4 are cooled. The temperature of the sample 4 is determined by the balance of an amount of heat input from the charged particles, a heat generation amount of the heater element, and an exhaust heat amount to the coolant.

With the above-described structure, when the high frequency power is applied to the electrode block 1, the insulator 10 becomes a component of the impedance, and the high frequency electric current is hindered. Therefore, there is a possibility that the charged particles in the plasma 33 in an amount capable of realizing a desired processing rate are hard to collide against the sample 4.

In this embodiment, the connection layer 11 having conductivity, which is arranged in a ring shape to surround the insulator 10, is arranged along the outer periphery position of the insulator 10 having a disk shape and a diameter smaller than that of the conductor 9. The connection layer 11 is joined to connect the outer peripheral side portion of the top surface of the electrode block 1 and the outer peripheral side portion of the conductor 9, and the high frequency power supplied to the electrode block 1 is supplied to the conductor 9 through it, so that its loss during supplying is reduced.

The connection layer 11 may be arranged inside the outer edge of the top surface of the conductor 9 or the electrode block 1, namely the outer edge of the connection layer 11 may be positioned inside the outer edge of the top surface of the conductor 9 or the electrode block 1. In this case, to prevent the connection layer 11 having conductivity from being exposed directly to the processing chamber 23 or the plasma 33 or the process gas 25 formed within it, an adhesive layer of another insulating material may be coated by arranging on the outer peripheral side of the outer edge of the connection layer 11 against the plasma or the like. In addition, if it is hard to arrange the connection layer 11 in view of mounting, the conductor 9 and the high frequency power source 5 may be connected electrically to supply directly the high frequency power to the conductor 9.

Similar to the above embodiment, this structure increases the dielectric constant of the second sintered body 3-2 to a level larger than that of the first sintered body 3-1 by mixing an additive, thereby suppressing the impedance of the electrostatic chuck 102 or the sintered body 3 as whole. Therefore, the high frequency power supplied from the high frequency power source 5 is applied efficiently to a sheath formed on the sample 4 during etching.

Thus, it becomes possible to collide ions, which are the charged particles, from inside the plasma 33 to the sample 4 efficiently, and good etching performance can be obtained by the interaction between the reaction active species (radical) and the charged particles (ions).

After the etching process is completed, the sample 4 is taken out from the processing chamber 23, and the inner wall of the processing chamber 23 is cleaned. If a wafer is not positioned on the top surface of the sample stage 101 at the time of cleaning, the top surface of the sintered body 3 forming the top surface of the sample stage 101 is exposed directly to plasma, but the first sintered body 3-1 forming the top surface of the sintered body 3 which is an attraction surface for the sample 4 is formed of a sintered body, and a change with time of the attraction force and generation of contaminating matters can be suppressed because a Coulomb attraction system is adopted.

The invention described in the above embodiment is not limited to the above-described plasma processing apparatus but can be diverted to other apparatus requiring precise wafer temperature control, such as an ashing device, a sputtering device, an ion implanting device, a resist coating device, a plasma CVD device, a flat-panel display manufacturing apparatus, a solar cell manufacturing device, etc.

1. A plasma processing apparatus, comprising:
a processing chamber arranged within a vacuum chamber with its inner space decompressed, and a sample stage arranged within the processing chamber with a sample to be processed placed on its top surface, wherein plasma is formed using a process gas supplied into the processing chamber above the sample stage to perform processing of the sample, wherein:
the sample stage is provided with a metal block which has therein a passage for flowing a coolant and to which high frequency power is supplied during the processing of the sample and an electrostatic chuck which is arranged on the block and on which the sample is positioned and electrostatically chucked, and
the electrostatic chuck is provided with film electrodes to which power for attraction of the sample is supplied, and upper and lower plate-like sintered bodies joined mutually with the electrodes interposed between them from above and below, and the lower sintered body has a dielectric constant higher than that of the upper sintered body.

2. The plasma processing apparatus according to claim 1, wherein the upper sintered body has a volume resistivity larger than that of the lower sintered body.

3. The plasma processing apparatus according to claim 1, wherein the lower sintered body has a thickness larger than that of the upper sintered body.

4. The plasma processing apparatus according to claim 1, wherein the upper sintered body is formed of pure ceramics.

5. The plasma processing apparatus according to claim 1, comprising
a film heater arranged above the block and below the electrostatic chuck, and a plate-like member arranged above the heater and below the electrostatic chuck in a state insulated from the block, and having a diameter larger than the heater and heat conductance.

6. The plasma processing apparatus according to claim 5, wherein the heater is arranged within an insulation layer which is arranged in a state interposed between the plate-like member and the top surface of the block.
